(19) United States
(12) Patent Application Publication
(10) Pub. No.: US 2025/0248141 A1
(43) Pub. Date: Jul. 31, 2025

(54) INTEGRATED CIRCUIT DEVICE INCLUDING A BOND-BASED CAPACITOR

(71) Applicant: Taiwan Semiconductor Manufacturing Company, Ltd., Hsinchu (TW)

(72) Inventors: Ping-Chieh Chin, Tainan City (TW); Feng-Chi Hung, Chu-Bei City (TW); Jen-Cheng Liu, Hsin-Chu City (TW); Wen-I Hsu, Tainan City (TW)

(21) Appl. No.: 18/425,224

(22) Filed: Jan. 29, 2024

(51) Int. Cl. H01L 27/146

(52) U.S. Cl. CPC H10F 39/026; H10F 39/8037; H10F 39/804; H10F 39/811

(57) ABSTRACT

Some embodiments relate to an integrated circuit (IC) device including a first IC die and a second IC die. The first IC die includes first and second conductive structures at a first surface of the first IC die, and the first and second conductive structures are laterally separated by a first dielectric structure. The second IC die includes third and fourth conductive structures at a first surface of the second IC die, and the third and fourth conductive structures are laterally separated by a second dielectric structure. The first surface of the first IC die faces the first surface of the second IC die such that the first conductive structure vertically contacts the third conductive structure to form a first capacitor electrode, and the second conductive structure vertically contacts the fourth conductive structure to form a second capacitor electrode. The first and second capacitor electrodes form a capacitor.

### BACKGROUND

While innovation in integrated circuit (IC) design is often directed to reducing the size and increasing the speed of transistors, such as for various types of digital electronics, the incorporation of analog components, such as capacitors, within IC devices remains an important aspect of IC design. For example, complementary metal-oxide-semiconductor (CMOS) image sensor (CIS) devices may incorporate capacitors for storage of charge collected in corresponding photosensitive components. Consequently, the overall size of such capacitors relative to their electrical characteristics may directly impact various aspects of the CIS device, such as the number of pixels employed in the device, the dynamic range exhibited by the pixels, and so on.

### BRIEF DESCRIPTION OF THE DRAWINGS

Aspects of the present disclosure are best understood from the following detailed

description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic view of some embodiments of a portion of an IC imaging device employing a bond-based capacitor, according to the present disclosure.

FIG. 2 illustrates a conceptual graph of a pixel signal-to-noise ratio (SNR) versus light exposure of some embodiments of an IC imaging device employing a bond-based capacitor, according to the present disclosure.

FIG. 3 illustrates a cross-sectional view of some embodiments of a portion of an IC imaging device employing a bond-based capacitor, according to the present disclosure.

FIG. 4 illustrates a cross-sectional view of some embodiments of a portion of the IC imaging device of FIG. 3, according to the present disclosure.

FIGS. 5A through 5L illustrate cross-sectional views of some embodiments of an IC imaging device employing a bond-based capacitor at various stages of manufacture, according to the present disclosure.

FIG. 6 illustrates a methodology of forming an IC imaging device employing a bond-based capacitor, in accordance with some embodiments of the present disclosure.

FIGS. 7A through 7C illustrate plan views of some embodiments of grounding arrangements of an IC imaging device employing a bond-based capacitor, according to the present disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some IC designs, a capacitor may consume a significant volume of an IC device relative to transistors and other components employed therein based on the value of the capacitance, the magnitude of voltage expected across the capacitor, and other factors. The volume consumed by the capacitor may be greatly increased by the number of such capacitors implemented in the device. For example, in an IC imaging device, one or more capacitors may be employed per pixel to store the charge generated from the light captured by the photodetector corresponding to that pixel. Consequently, the volume consumed by one or more capacitors associated with each pixel may negatively impact the number of pixels that may be realized in an IC imaging device of a given size.

To address these issues, the present disclosure provides some embodiments of an IC device that employs a bond-based capacitor. In some embodiments, the capacitor may be constructed using bonds between IC dies and/or wafers. For example, a multiple-material heat-based bonding process may be employed in which a surface of two separate IC dies and/or wafers having corresponding conductive structures and intervening dielectric regions are placed together and heated to bond the surfaces of the two IC dies and/or wafers together by way of bonding the corresponding conductive structures together and bonding the corresponding dielectric regions together.

In some embodiments, an IC device may include a first IC die and a second IC die. The first IC die may include first and second conductive structures at a surface of the first IC die, where the first and second conductive structures are laterally separated by a first dielectric structure. Also, the second IC die may include third and fourth conductive structures at a surface of the second IC die, where the third and fourth conductive structures are laterally separated by a second dielectric structure. The surfaces of the first and second IC dies may face each other such that the first conductive structure vertically contacts the third conductive structure to form a first capacitor electrode, and the second conductive structure vertically contacts the fourth conductive structure to form a second capacitor electrode. The first capacitor electrode is laterally separated from the second capacitor electrode by the first and second dielectric structures to form a capacitor.

Thus, in some embodiments, an interfacing structure between two IC dies of an IC device may be additionally employed as a capacitor, thus using a portion of an IC device that would normally be dedicated strictly for circuit connections to support an electronic circuit component. In some embodiments, this dual capability of an interfacing structure may result in better utilization of the available volume within an IC device. Further, in some embodiments, the use of such a capacitor may improve or enhance some functionality or characteristic of an IC device that employs multiple IC dies or wafers.

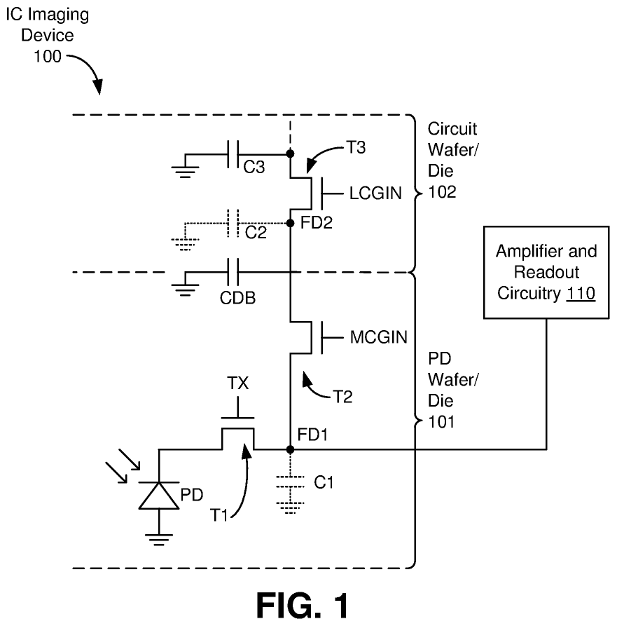

For example, FIG. 1 illustrates a schematic view of some embodiments of a portion of an IC imaging device 100 employing a bond-based capacitor CDB, according to the present disclosure. As presented, FIG. 1 depicts a portion of a single pixel of multiple pixels incorporated in IC imaging device 100 to simplify the following discussion.

IC imaging device 100 includes at least a first and a second wafer/die: a photodetector (PD) wafer/die 101 and a circuit wafer/die 102. In some embodiments, PD wafer/die 101 includes the photodetectors (e.g., photodiodes) for the pixels implemented in IC imaging device 100, as well as some of the circuitry closely coupled with the photodetectors, such as transfer transistors, capacitors for storing charge generated by the photodetectors, and so on. In some embodiments, circuit wafer/die 102 includes other circuitry (e.g., in addition to the circuitry provided in PD wafer/die 101), such as circuitry that facilitates the generation of digital data representing the amount of light received by the photodetectors during sequential time periods. While only two wafers/dies 101 and 102 are depicted in FIG. 1, one or more additional wafers/dies may be included in IC imaging device 100 in other embodiments.

PD wafer/die 101 of IC imaging device 100 may include, for example, at least one photodetector PD (e.g., a photodiode, such as a PN diode) for a pixel. In some embodiments, photodetector PD has an anode coupled to a reference voltage (e.g., ground). A first transistor T1 (e.g., a transfer transistor with a transfer signal TX driving a gate of the transfer transistor) has a first source-drain connection electrically coupled to a cathode of photodetector PD, a second source-drain connection electrically coupled to a first source-drain connection of a second transistor T2 (e.g., a first conversion gain mode transistor, with a middle conversion gain selection input signal MCGIN driving a gate of second transistor T2) by way of a first floating diffusion (FD) region FD1.

Disposed in circuit wafer/die 102 may be a third transistor T3 (e.g., a second conversion gain mode transistor, with a low conversion gain selection input signal LCGIN driving a gate of third transistor T3). In some embodiments, at an interface structure of PD wafer/die 101 and circuit wafer/die 102, a second source-drain connection of second transistor T2 may be coupled to a first source-drain connection of third transistor T3 by way of a second floating diffusion region FD2 residing at or near the interface structure.

Also shown in FIG. 1 are four capacitors: a first capacitor C1 (e.g., an inherent capacitance) associated with first floating diffusion region FD1, a second capacitor C2 (e.g., an inherent capacitance) associated with second floating diffusion region FD2, a third capacitor C3 in circuit wafer/die 102, and a bond-based capacitor (e.g., bond-based capacitor CDB) at the interface structure of PD wafer/die 101 and circuit wafer/die 102, as discussed in greater detail below. In some embodiments, first capacitor C1 and second capacitor C2 couple first floating diffusion region FD1 and second floating diffusion region FD2 to a reference voltage (e.g., ground). Also, in some embodiments, third capacitor C3 electrically couples a second source-drain connection of third transistor T3 to a reference voltage (e.g., ground), and bond-based capacitor CDB electrically couples the first source-drain connection of third transistor T3 and the second source-drain connection of second transistor T2 to a reference voltage (e.g., ground).

In some embodiments, the bond-based capacitor may include capacitor electrodes that are respectively formed by pairs of conductive bonding structures disposed on opposing sides of the interface structure of PD wafer/die 101 and circuit wafer/die 102. The pairs of conductive bonding structures vertically contact one another to form capacitor plates that vertically straddle the interface structure. The capacitor plates are laterally separated from one another along the interface structure.

In some embodiments, first capacitor C1, second capacitor C2, third capacitor C3, and bond-based capacitor CDB, in conjunction with first transistor T1, second transistor T2, and third transistor T3, are configured according to a lateral overflow integration capacitor (LOFIC) arrangement, in which one or more capacitors are coupled to first floating diffusion region FD1 by transistors T1, T2, and T3. More specifically, in some embodiments, the charge transferred from photodetector PD (e.g., by way of first transistor T1 turning on) may be read, in order, in a high conversion gain (HCG) mode (e.g., when transistors T2 and T3 are off), in a mid conversion gain (MCG) mode (e.g., when transistor T2 is on and transistor T3 is off), and in a low conversion gain (LCG) mode (e.g., when transistors T2 and T3 are on).

In some embodiments, the resulting voltage potentials at first floating diffusion region FD1 in the various conversion gain modes may then be provided to amplifier and readout circuitry 110. In some embodiments, amplifier and readout circuitry 110 may include a source follower transistor, a row select transistor, and/or other circuitry. Also, in some embodiments, the second source-drain connection of third transistor T3 may be coupled to other circuitry, such as a reset transistor (not explicitly shown in FIG. 1) that may reset the charges and voltages of the pixel to begin another charge accumulation cycle at photodetector PD.

In some embodiments, the amount of gain in each conversion gain mode is based on (e.g., proportional to) the amount of capacitance coupled to first floating diffusion region FD1 in that mode divided by the total capacitance (Cₜₒₜₐₗ) of the first capacitor C1, second capacitor C2, third capacitor C3, and bond-based capacitor CDB. As a result, in HCG mode, the gain GHCG is proportional to C1/Cₜₒₜₐₗ. In MCG mode, the gain GMCG is proportional to (C1+C2+CDB)/Cₜₒₜₐₗ. In LCG mode, the gain GLCG is proportional to (C1+C2+CDB+C3)/Cₜₒₜₐₗ.

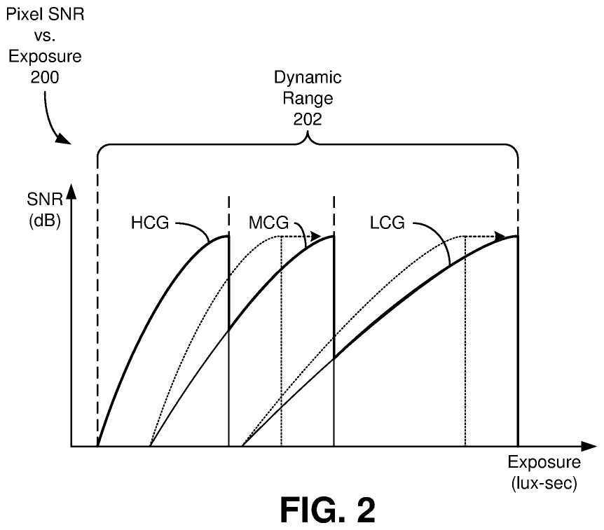

FIG. 2 illustrates a conceptual graph 200 of a pixel signal-to-noise ratio (SNR) (e.g., in decibels (dB)) versus light exposure (e.g., in lux-seconds (lux-sec)) of some embodiments of an IC imaging device 100 employing a bond-based capacitor CDB, according to the present disclosure. The solid dark graph line of FIG. 2 denotes the resulting overall gain due to each conversion gain mode HCG, MCG, and LCG resulting from the use of bond-based capacitor CDB. Moreover, the dotted lines denote the MCG mode and the LCG mode in the absence of bond-based capacitor CDB. Accordingly, the use of bond-based capacitor CDB alters the gain of those two conversion modes (as shown by way of the dashed arrows in FIG. 2), thus extending the overall dynamic range 202 provided by IC imaging device 100.

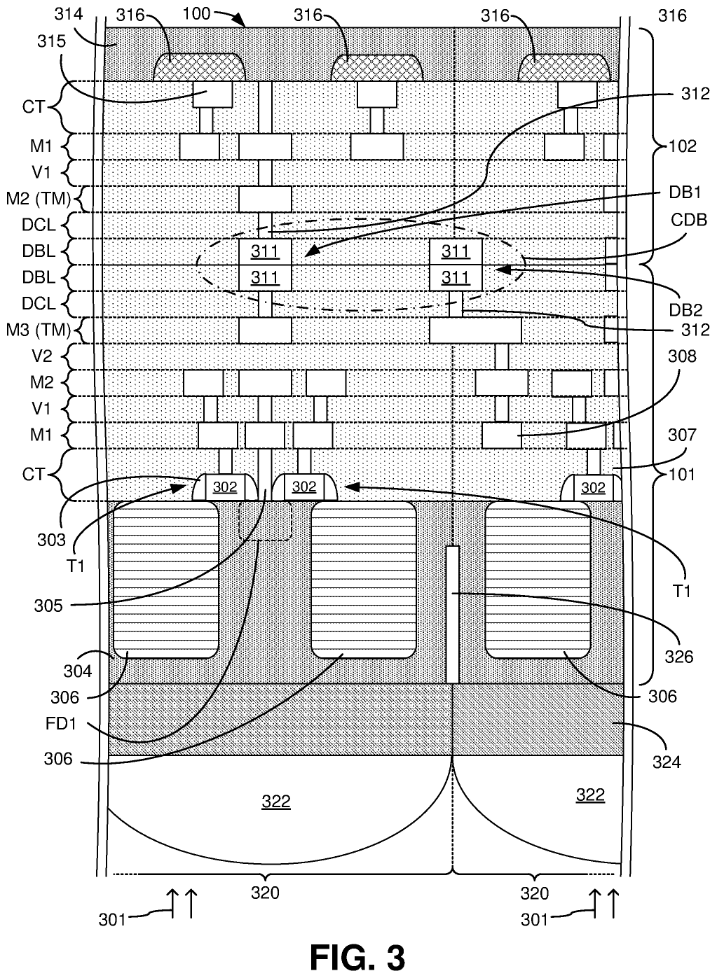

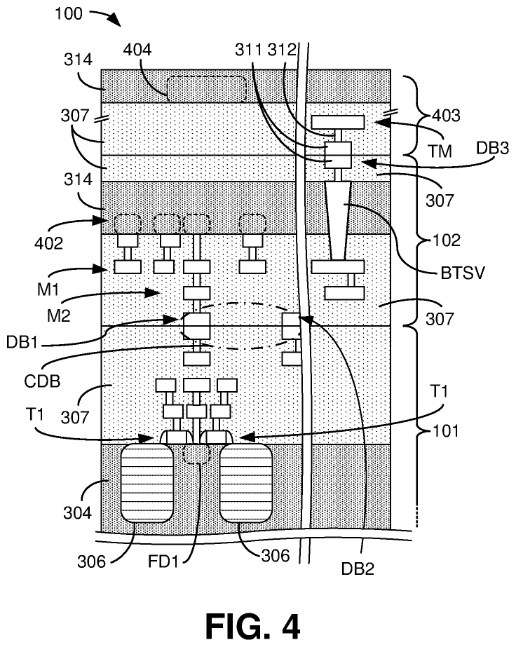

FIG. 3 illustrates a cross-sectional view of some embodiments of a portion (e.g., portions of pixel regions 320) of an IC imaging device 100 employing a bond-based capacitor CDB, according to the present disclosure. In some embodiments, as depicted in FIGS. 3 and 4 (discussed below), each pixel region 320 may employ a dual-photodetector configuration. However, one or more photodetectors may be employed in a pixel in other arrangements, such as a single-photodetector configuration, a quad-photodetector configuration, and the like.

Beginning with PD wafer/die 101, a semiconductor substrate 304 (e.g., silicon) may include photosensitive regions 306 to serve as photodetectors PD (e.g., PN photodiodes or “pinned” photodiodes) in conjunction with the surrounding area of substrate 304. In some embodiments, substrate 304 may be p-doped silicon, and photosensitive region 306 may be doped with ions to create n-doped regions. Between photosensitive regions 306 may be first floating diffusion region FD1. Photosensitive regions 306 may be configured to receive light 301 through a backside surface of substrate 304 by way of a lens 322 and an optical filter 324 (e.g., a color filter, a bandwidth filter, or the like) for each pixel region 320, as indicated in FIG. 3. In some embodiments, an isolation structure 326 (e.g., a dielectric structure) may be disposed within substrate 304 and vertically oriented between photosensitive regions 306 of adjacent pixel regions 320 (e.g., to retain photons captured via lenses 322 within their respective pixel regions 320).

One or more dielectric layers 307, within which multiple conductive structures are located, may be disposed over substrate 304. In some embodiments, a gate structure 302 and associated sidewall spacer 303 may be formed over the semiconductor substrate 304 adjacent photosensitive region 306 for each associated photodiode. In some embodiments, gate structure 302 may be made of polycrystalline silicon (poly-Si). Also, in some embodiments, gate structure 302 may be controlled as a transfer gate to transfer charge collected in the photodiode via first floating diffusion region FD1 over some period of time to a measurement node via a measurement contact 305 adjacent (e.g., between) gate structures 302.

As illustrated in FIG. 3, gate structures 302, sidewall spacers 303, and measurement contact 305 may be disposed within a contact layer CT. Further, multiple conductive (e.g., metal) layers M1, M2, and M3 and intervening via layers V1 and V2 may be disposed over contact layer CT to facilitate electrical connections between various components of PD wafer/die 101, such as between measurement contact 305 (e.g., serving as the second drain-source connection of first transistor T1) and the first drain-source connection of second transistor T2 (not explicitly shown in FIG. 3). Further, the uppermost metal layer M3 may also be viewed as the top metal layer TM in some embodiments. In other embodiments, greater or fewer numbers of conductive layers and via layers may be used in both PD wafer/die 101 and circuit wafer/die 102.

In some embodiments, disposed over top metal layer TM may be a bond contact layer DCL and a bond layer DBL. In some embodiments, bond layer DBL may include first and second conductive structures 311, and bond contact layer DCL may include first and second conductive contacts 312 that couple first and second conductive structures 311, respectively, to other conductive structures of top metal layer TM. In some embodiments, first conductive structure 311 may be electrically coupled by way of first conductive contact 312 to the second source-drain connection of second transistor T2 (not explicitly shown in FIG. 3), and the second conductive structure 311 may be electrically coupled to a reference voltage structure (e.g., by way of conductive element 308) using second conductive contact 312.

Proceeding with circuit wafer/die 102, a semiconductor substrate 314 (e.g., silicon) may include doped regions 316 that may be operated as source-drain regions for transistors that provide functionality (e.g., reset transistor, source follower transistor, etc.) related to the pixels of IC imaging device 100. One or more dielectric layers 307, within which multiple conductive structures are located, may be disposed over substrate 314. In FIG. 3, circuit wafer/die 102 is disposed in an inverse orientation relative to PD wafer/die 101 to facilitate bonding therebetween. In some embodiments, conductive structures may include polycrystalline silicon (poly-Si) structures 315 coupling doped regions 316 to other portions of the conductive structures. In some embodiments, the poly-Si structures 315 are disposed with a contact layer CT. Further, conductive (e.g., metal) layers M1 and M2, and intervening via layer V1, may be disposed over contact layer CT to facilitate electrical connections between various components of circuit wafer/die 102. The uppermost metal layer M2 may also be viewed as top metal layer TM of circuit wafer/die 102 in some embodiments.

In some embodiments, as in the case of PD wafer/die 101, disposed over top metal layer TM of circuit wafer/die 102 may be a bond contact layer DCL and a bond layer DBL. In some embodiments, bond layer DBL may include third and fourth conductive structures 311, and bond contact layer DCL may include third and fourth conductive contacts 312 that couple third and fourth conductive structures 311, respectively, to other conductive structures of top metal layer TM. In some embodiment, third conductive structure 311 may be electrically coupled by way of third conductive contact 312 to the first source-drain connection of third transistor T3 (not explicitly shown in FIG. 3). Further, in some embodiments, fourth conductive structure 311 may not be connected to a corresponding contact or another other conductive structure below bond layer DBL at the surface of circuit wafer/die 102.

In some embodiments, bond layer DBL of PD wafer/die 101 and bond layer DBL of circuit wafer/die 102 are bonded together (e.g., by way of heat-based bonding) such that first conductive structure 311 of PD wafer/die 101 and third conductive structure 311 of circuit wafer/die 102 make contact to form a first bond DB1 that provides a first capacitor electrode or plate. Additionally, due to the bonding, third conductive structure 311 of PD wafer/die 101 and fourth conductive structure 311 of circuit wafer/die 102 make contact as well to form a second bond DB2 that provides a second capacitor electrode or plate. Further, in some embodiments, dielectric layers 307 of bond layer DBL of PD wafer/die 101 and circuit wafer/die 102 also make contact. Consequently, first bond DB1 may be disposed over one pixel region 320 (e.g., centrally located within pixel region 320 in a plan view), and second bond DB2 may be disposed between (e.g., at a boundary between) pixel regions 320.

Consequently, as indicated in FIG. 3, first, second, third, and fourth conductive structures 311, as well as the dielectric structures disposed therebetween, form capacitor CDB (e.g., a metal-oxide-metal (MOM) capacitor). Thus, in some embodiments, the circuit functionality provided by the first, second, third, and fourth conductive structures 311 is produced without significant additional structures beyond those that would otherwise be provided by the electrical connections between PD wafer/die 101 and circuit wafer/die 102.

FIG. 4 illustrates a cross-sectional view of some embodiments of a portion of IC imaging device 100 of FIG. 3, according to the present disclosure. More specifically, in addition to the portion of IC imaging device 100 depicted in FIG. 3, FIG. 4 illustrates additional circuitry 402 provided in substrate 314 of circuit wafer/die 102, interconnected by way of conductive layers M1 and/or M2, but omits lenses 322 and optical filters 324 of FIG. 3. In some embodiments, additional circuitry 402 may include one or more of a row select transistor, a source follower transistor, a reset transistor, a column readout capacitor, and/or circuitry (e.g., timing circuitry) to generate input (e.g., gate) signals for the various transistors.

To facilitate other functionality (e.g., higher-level storage and processing functionality) related to the pixels of IC imaging device 100, at least one additional (e.g., application-specific integrated circuit (ASIC)) wafer/die 403 may be attached (e.g., bonded) to circuit wafer/die 102. In some embodiments, a backside through-silicon via BTSV may be disposed in substrate 314 and into adjacent one or more dielectric layers 307 to contact a conductive structure (e.g., a conductive layer M1, M2, or the like). Further, in some embodiments, an additional dielectric layer 307 may be disposed over a backside of substrate 314 opposite PD wafer/die 101, and a fifth conductive structure 311 and associated fifth conductive contact 312 may be disposed therein.

Additional wafer/die 403 may include higher-level circuitry 404 (e.g., analog-to-digital conversion (ADC), digital storage of pixel data, and so on) within a substrate 314. Formed over substrate 314 may be a dielectric layer 307 incorporating a conductive structure that may include a top conductive (e.g., metal) layer TM. In some embodiment, a conductive structure of top conductive layer TM may be electrically connected with a sixth conductive structure 311 and associated sixth conductive contact 312. Additional wafer/die 403 may be attached (e.g., bonded) to circuit wafer/die 102, which may include the forming of a third bond DB3 that includes fifth and sixth conductive structures 311 and associated fifth and sixth conductive contacts 312. Consequently, higher-level circuitry 404 may be electrically coupled via third bond DB3 and backside through-silicon via BTSV to circuitry within circuit wafer/die 102.

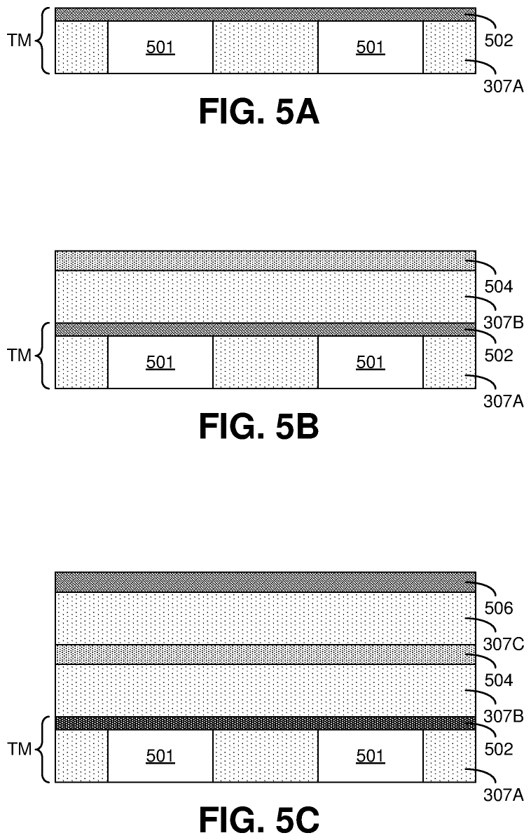

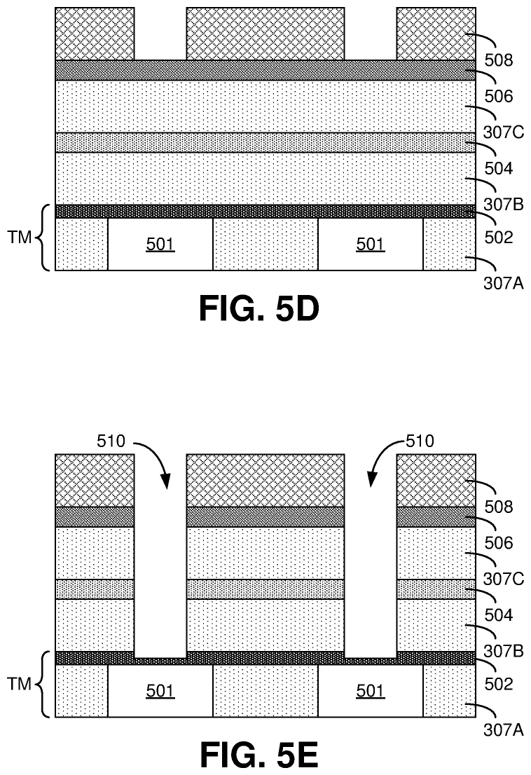

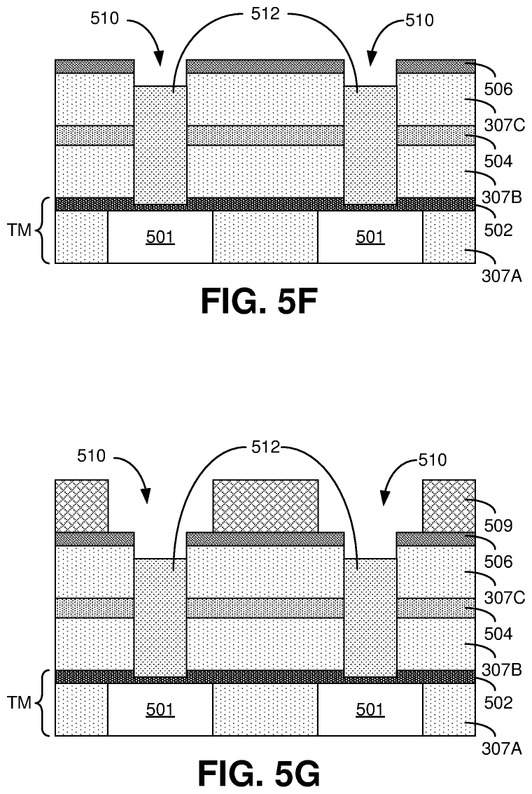

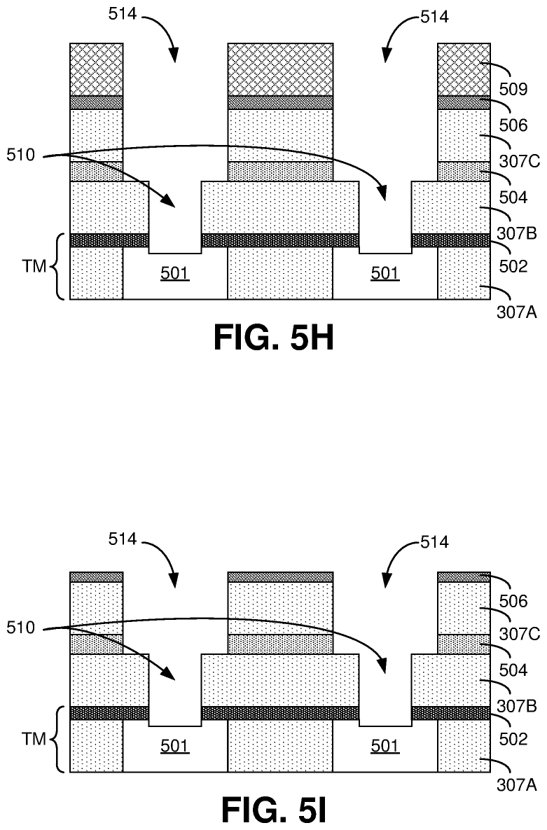

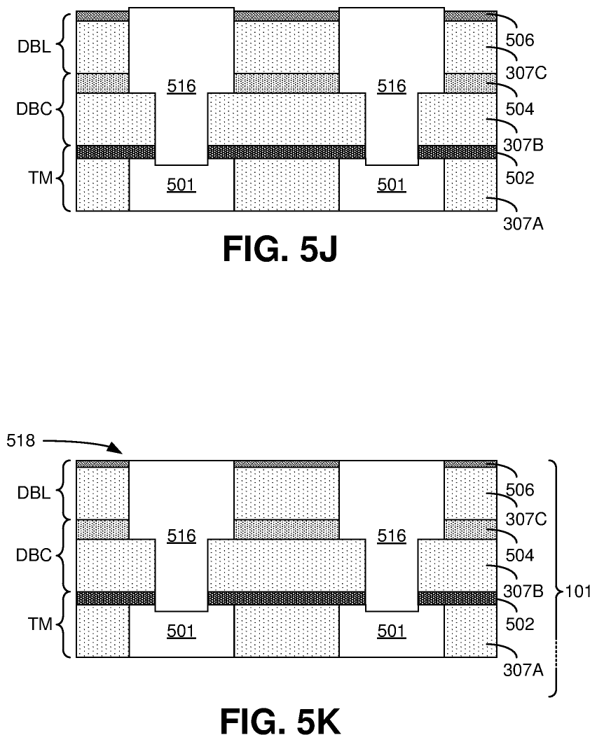

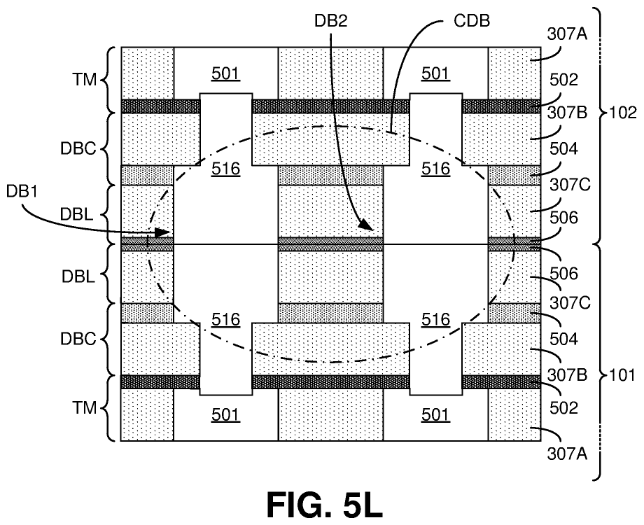

FIGS. 5A through 5L illustrate cross-sectional views of some embodiments of an IC imaging device 100 employing a bond-based capacitor CDB at various stages of manufacture, according to the present disclosure. Although FIGS. 5A through 5L are described as a series of acts, it will be appreciated that these acts are not limiting in that the order of the acts within each series can be altered in other embodiments, and the methods disclosed are also applicable to other structures. In other embodiments, some acts that are illustrated and/or described may be omitted in whole or in part. In particular, the acts described below are directed to the forming of the bonds DB1 and DB2 that form bond-based capacitor CDB to simplify the following discussion.

For example, FIG. 5A illustrates top conductive (e.g., metal) layer TM of what will result in PD wafer/die 101. Top conductive layer TM includes first and second conductive structures 501 in a first dielectric layer 307A. In some embodiments, first dielectric layer 307A, as well as at least one or more other dielectric layers, may include one or more dielectric materials, including, but not limited to, silicon oxide (SiOx) (e.g., silicon oxide (SiO2)), silicon nitride (SiN), silicon carbide (SiC), carbon-doped silicon dioxide, silicon oxynitride, borosilicate glass (BSG), phosphorus silicate glass (PSG), borophosphosilicate (BPSG), fluorosilicate glass (FSG), undoped silicate glass (USG), a porous dielectric material, or the like.

In some embodiments, a capping layer 502 (e.g., including a dielectric material) may be formed (e.g., deposited) over first and second conductive structures 501 (e.g., to prevent oxidation of first and second conductive structures 501 in subsequent acts).

FIG. 5B illustrates the forming (e.g., deposition) of a second dielectric layer 307B over first and second conductive structures 501 (and, if present, capping layer 502). In some embodiments, second dielectric layer 307B may include the same or similar materials as first dielectric layer 307A. In some embodiments, an etch stop layer 504 may be formed (e.g., deposited) over second dielectric layer 307B (e.g., to facilitate a subsequent etching act). Etch stop layer 504 may include one or more of silicon nitride (SiN), silicon carbide (SiC), silicon carbonitride (SiCN), or another dielectric material.

FIG. 5C illustrates the forming (e.g., deposition) of a third dielectric layer 307C over second dielectric layer 307B (and, if present, etch stop layer 504). In some embodiments, third dielectric layer 307C may include the same or similar materials as first dielectric layer 307A. In some embodiments, a buffer layer 506 (e.g., including a dielectric material) may be formed (e.g., deposited) over third dielectric layer 307C (e.g., to provide a surface upon which a chemical-mechanical planarization (CMP) act may be performed).

FIG. 5D illustrates the forming (e.g., deposition and patterning) of a first photoresist layer 508 over third dielectric layer 307C (and, if present, buffer layer 506). In some embodiments, first photoresist layer 508 may be patterned to facilitate etching of trenches having a width for conductive contacts 312 (FIG. 3) over first and second conductive structures 501.

FIG. 5E illustrates the removal (e.g., etching) of material to form trenches 510 over first and second conductive structures 501. In some embodiments, each trench 510 extends at least through buffer layer 506 (if present), third dielectric layer 307C, etch stop layer 504 (if present), and second dielectric layer 307B. Further, in some embodiments, each trench 510 may extend into capping layer 502, as illustrated in FIG. 5E.

FIG. 5F illustrates the removal of first photoresist layer 508 from third dielectric layer 307C (or buffer layer 506, if present). In some embodiments, the removal of first photoresist layer 508 may result in the removal of a small portion of buffer layer 506. Further, in some embodiments, trenches 510 are at least partially filled with a sacrificial fill material 512 (e.g., to be removed in a later etching act). In some embodiments, sacrificial fill material 512 may fill each trench 510 up to within third dielectric layer 307C.

FIG. 5G illustrates the forming (e.g., deposition and patterning) of a second photoresist layer 509 over third dielectric layer 307C (and, if present, buffer layer 506). In some embodiments, second photoresist layer 509 may be patterned to facilitate etching of trenches having a width for conductive structures 311 (FIG. 3) over first and second conductive structures 501. In some embodiments, the width of conductive structures 311 is greater than the width of conductive contacts 312.

FIG. 5H illustrates the removal (e.g., etching) of material to form trenches 514 over first and second conductive structures 501. In some embodiments, each trench 514 extends at least through buffer layer 506 (if present), third dielectric layer 307C, and etch stop layer 504 (if present). In some embodiments, this etching act may also remove sacrificial fill material 512 completely, and may extend trenches 514 through capping layer 502, and possibly into first and second conductive structures 501.

FIG. 5I illustrates the removal of second photoresist layer 509 from third dielectric layer 307C (or buffer layer 506, if present). In some embodiments, the removal of first photoresist layer 509 may result in the removal of a small portion of buffer layer 506.

FIG. 5J illustrates the forming (e.g., deposition) of conductive elements 516 in trenches 514 up to at least an upper surface of buffer layer 506 (if present) or third dielectric layer 307C. In some embodiments, conductive elements 516 may include copper or another metal or metal alloy. Further, trenches 514 may be overfilled such that conductive elements 516 extend slightly above the upper surface of buffer layer 506 (if present) or third dielectric layer 307C. In some embodiments, conductive elements 516 each include a conductive structure 311 and a conductive contact 312 (FIG. 3).

FIG. 5K illustrates the planarizing 518 or polishing of a top surface of conductive elements 516 and the upper surface of buffer layer 506 (if present) or third dielectric layer 307C. In some embodiments, the planarizing or polishing may include chemical-mechanical planarization (CMP) or another planarizing technique.

While the operations associated with FIGS. 5A through 5K are described above as being performed in conjunction with the fabrication of PD wafer/die 101, these same operations are also performed with respect to the fabrication of circuit wafer/die 102, in some embodiments.

FIG. 5L illustrates the bonding (e.g., via heat-based bonding) of an upper surface of PD wafer/die 101 with an upper surface of circuit wafer/die 102. In some embodiments, this bonding is performed by placing the upper surfaces of PD wafer/die 101 and circuit wafer/die 102 (e.g., at room temperature) together to bond third dielectric layers 307C (or buffer layers 506, if present), and then heating the resulting assembly to cause each of conductive elements 516 of PD wafer/die 101 to contact a corresponding one of conductive elements 516 of circuit wafer/die 102. This bonding may thus result in the formation of first bond DB1 and second bond DB2 to generate bond-based capacitor CDB. Consequently, a capacitor may be created by bonding technology focused primarily on the connection of two IC wafers and/or dies.

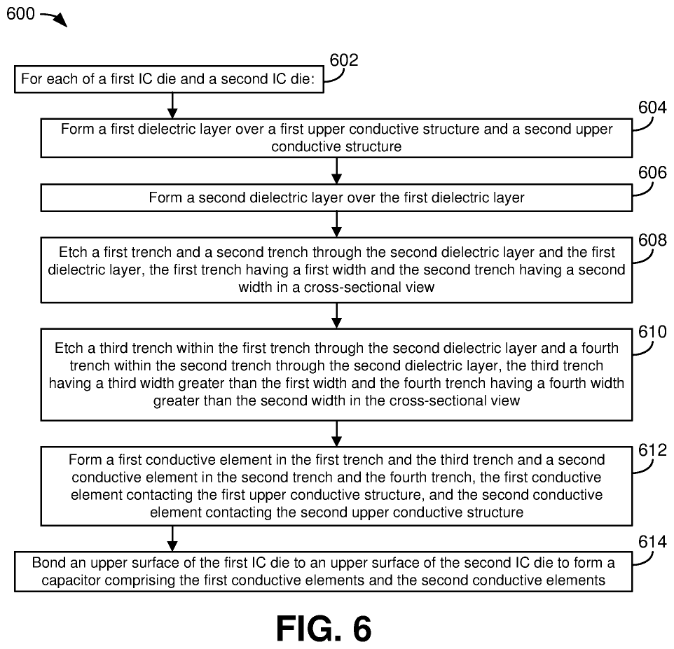

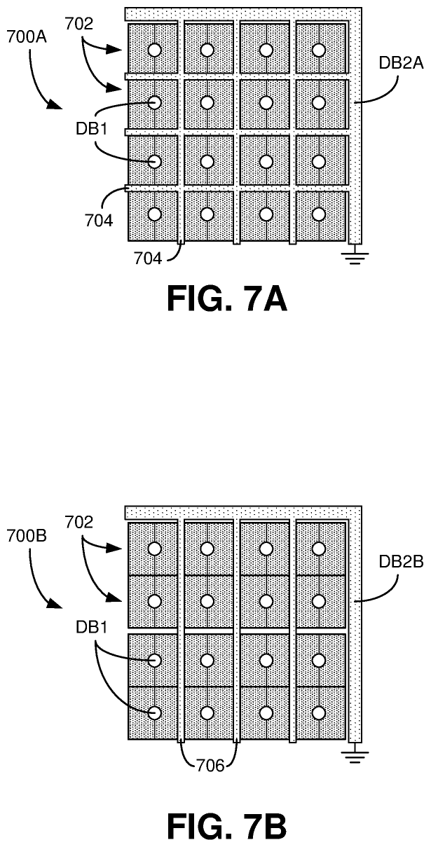

FIG. 6 illustrates a methodology 600 of forming an IC imaging device (e.g., IC imaging device 100 of FIG. 3) employing a bond-based capacitor (e.g., bond-based capacitor CDB of FIG. 3), in accordance with some embodiments of the present disclosure. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

Acts 602 through 614 may correspond, for example, to the structures previously illustrated in FIGS. 5A through 5L. At Act 602, for example, a following series of acts (e.g., Acts 604 through 620) are performed for each of a first IC die (e.g., PD wafer/die 101 of FIG. 3) and a second IC die (e.g., circuit wafer/die 102 of FIG. 3).

At Act 604, a first dielectric layer (e.g., second dielectric layer 307B of FIG. 5B) is formed over a first upper conductive structure and a second upper conductive structure (e.g., conductive structures 501 of FIG. 5B). FIG. 5B illustrates a cross-sectional view of some embodiments corresponding to Act 604.

At Act 606, a second dielectric layer (e.g., third dielectric layer 307C of FIG. 5C) is formed over the first dielectric layer. FIG. 5C illustrates a cross-sectional view of some embodiments corresponding to Act 606.

At Act 608, a first trench and a second trench (e.g., trenches 510 of FIG. 5E) are etched through the second dielectric layer and the first dielectric layer, the first trench having a first width and the second trench having a second width in a cross-sectional view. FIGS. 5D and 5E illustrate cross-sectional views of some embodiments corresponding to Act 608.

At Act 610, a third trench (e.g., one of trenches 514 of FIG. 5H) is etched within the first trench through the second dielectric layer, and a fourth trench (e.g., another of trenches 514 of FIG. 5H) is etched within the second trench through the second dielectric layer. In some embodiments, the third trench has a third width greater than the first width, and the fourth trench as a fourth width greater than the second width in the cross-sectional view. FIGS. 5G and 5H illustrate cross-sectional views of some embodiments corresponding to Act 610.

At Act 612, a first conductive element (e.g., one of conductive elements 516) is formed in the first trench and the second trench, and a second conductive element (e.g., another of the conductive elements 516) is formed in the third trench and the fourth trench. In some embodiments, the first conductive element contacts the first upper conductive structure, and the second conductive element contacts the second upper conductive structure. FIG. 5J illustrates a cross-sectional view of some embodiments corresponding to Act 612.

After the processing of the first IC die and the second IC die, as performed in Acts 604 through 612, at Act 614, an upper surface of the first IC die is bonded (e.g., via heat-based bonding) to an upper surface of the second IC die to form a capacitor (e.g., capacitor CDB of FIG. 5L) that includes the first conductive elements (e.g., forming bond DB1 of FIG. 5L) and the second conductive elements (e.g., forming bond DB2 of FIG. 5L). FIG. 5L illustrates a cross-sectional view of some embodiments corresponding to Act 614.

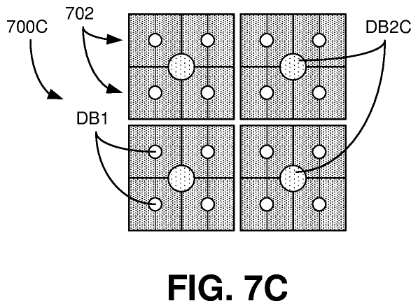

FIGS. 7A through 7C illustrate plan views of some embodiments of grounding arrangements 700A, 700B, and 700C, respectively, of an IC imaging device 100 employing a bond-based capacitor CDB, according to the present disclosure. In each of FIGS. 7A through 7C, each patterned square denotes a dual-photodetector pixel 702, where each pixel may include two corresponding photodetectors PD having associated photosensitive regions 306, as depicted in FIG. 3. Further, in each of FIGS. 7A through 7C, a first bond DB1 of each capacitor CDB is disposed between the photodetectors of each pixel 702, as depicted in FIG. 3 (e.g., approximately centered within the footprint of the corresponding pixel 702). Also, while each first bond DB1 is shown as having a circular shape in the plan view, other shapes (e.g., square, rectangular, and so on) are also possible in other embodiments.

In FIG. 7A, second bonds DB2 (as shown in FIG. 3) of pixels 702 may form a conductive mesh structure DB2A having a plurality of conductive segments 704, where conductive mesh structure DB2A is electrically coupled to a reference voltage (e.g., ground) structure. In some embodiments, each conductive segment 704 may extend along a periphery of multiple pixels 702 in the plan view. Consequently, as shown in FIG. 7A, conductive mesh structure DB2A may extend along at least two sides, and may extend along all four sides, of each pixel 702.

In FIG. 7B, second bonds DB2 of pixels 702 may form a conductive comb structure DB2B including a plurality of conductive branches 706, where conductive comb structure DB2B is electrically coupled to a reference voltage (e.g., ground) structure. In some embodiments, each conductive branch 706 may extend along a periphery of multiple pixels 702 in the plan view. Accordingly, as depicted in FIG. 7B, conductive comb structure DB2B may extend along at least one side, and may extend along as many as three sides, of each pixel 702.

In FIG. 7C, second bonds DB2 of pixels 702 may form a plurality of individual conductive structures DB2C in a plan view. In some embodiments, each of the conductive structures DB2C may be located at a periphery of each of one or more pixels 702 and may be electrically coupled to a reference voltage (e.g., ground) structure. For example, as illustrated in FIG. 7C, one conductive structure DB2C may be located at a periphery of four pixels 702 (e.g., at a corner of each of the four pixels 702). In some embodiments, an area of each conductive structure DB2C may be greater than each corresponding first bond DB1 of pixels 702 associated with conductive structure DB2C. Also, while each conductive structure DB2C is illustrated as having a circular shape in the plan view, other shapes (e.g., square, rectangular, and so on) are also possible in other embodiments.

Some embodiments relate to an IC device. The IC device includes a first IC die and a second IC die. The first IC die includes first and second conductive structures at a first surface of the first IC die, and the first and second conductive structures are laterally separated by a first dielectric structure. The second IC die includes third and fourth conductive structures at a first surface of the second IC die, and the third and fourth conductive structures are laterally separated by a second dielectric structure. The fourth conductive structure does not directly contact any other conductive structure below the first surface of the second IC die. The first surface of the first IC die faces the first surface of the second IC die such that the first conductive structure vertically contacts the third conductive structure to form a first capacitor electrode, the second conductive structure vertically contacts the fourth conductive structure to form a second capacitor electrode, and the first dielectric structure vertically contacts the second dielectric structure. The first and second capacitor electrodes and the first and second dielectric structures form a capacitor.

Some embodiments relate to another IC device. The IC device includes a first IC die and a second IC die. The first IC die includes a first plurality of conductive structures within a first dielectric structure disposed on a first substrate, and the first plurality of conductive structures and the first dielectric structure are arranged along a first surface of the first IC die. A second IC die includes a second plurality of conductive structures arranged within a second dielectric structure disposed on a second substrate, and the second plurality of conductive structures and the second dielectric structure are arranged along a first surface of the second IC die. The first surface of the first IC die faces and contacts the first surface of the second IC die to form a die interface. A plurality of capacitors straddle the die interface. The plurality of capacitors include a plurality of first capacitor plates and a plurality of second capacitor plates that are laterally separated along the die interface. The plurality of first capacitor plates and the plurality of second capacitor plates include the first plurality of conductive structures and the second plurality of conductive structures.

Some embodiments relate to a method. The method includes, for each of a first IC die and a second IC die: forming a first dielectric layer over a first upper conductive structure and a second upper conductive structure; forming a second dielectric layer over the first dielectric layer; etching a first trench and a second trench through the second dielectric layer and the first dielectric layer, the first trench having a first width and the second trench having a second width in a cross-sectional view; etching a third trench within the first trench through the second dielectric layer and a fourth trench within the second trench through the second dielectric layer, the third trench having a third width greater than the first width and the fourth trench having a fourth width greater than the second width in the cross-sectional view; and forming a first conductive element in the first trench and the third trench and a second conductive element in the second trench and the fourth trench, the first conductive element contacting the first upper conductive structure, and the second conductive element contacting the second upper conductive structure. The method also includes bonding an upper surface of the first IC die to an upper surface of the second IC die to form a capacitor that includes the first conductive elements and the second conductive elements.

It will be appreciated that in this written description, as well as in the claims below, the terms “first”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device, comprising:
a first IC die comprising a first conductive structure and a second conductive structure at a first surface of the first IC die, the first and second conductive structures laterally separated by a first dielectric structure, the second conductive structure being electrically connected to a reference voltage structure; and
a second IC die comprising a third conductive structure and a fourth conductive structure at a first surface of the second IC die, the third and fourth conductive structures laterally separated by a second dielectric structure, the fourth conductive structure not directly contacting any other conductive structure below the first surface of the second IC die;
wherein the first surface of the first IC die faces the first surface of the second IC die such that the first conductive structure vertically contacts the third conductive structure to form a first capacitor electrode, the second conductive structure vertically contacts the fourth conductive structure to form a second capacitor electrode, and the first dielectric structure vertically contacts the second dielectric structure, the first capacitor electrode, the second capacitor electrode, the first dielectric structure, and the second dielectric structure forming a first capacitor.

2. The IC device of claim 1, wherein the first IC die further comprises:
a substrate comprising a first photodetector;
a first transfer gate electrically coupled to the first photodetector; and
a first conversion gain mode transistor comprising:
a first source-drain connection electrically coupled to a source-drain connection of the first transfer gate; and
a second source-drain connection electrically coupled to the first conductive structure.

3. The IC device of claim 2, wherein the second IC die further comprises:
a second capacitor; and
a second conversion gain mode transistor comprising:
a first source-drain connection electrically coupled to the third conductive structure; and
a second source-drain connection electrically coupled to the second capacitor.

4. The IC device of claim 3, wherein the first and second conversion gain mode transistors and the first and second capacitors are configured in a lateral overflow integration capacitor (LOFIC) configuration providing three conversion gain levels.

5. The IC device of claim 2, wherein:
the substrate further comprises a second photodetector proximate the first photodetector;
the first IC die further comprises a second transfer gate electrically coupled to the second photodetector; and
the first source-drain connection of the first conversion gain mode transistor is electrically coupled to a source-drain connection of the second transfer gate.

6. The IC device of claim 5, wherein:
the first and third conductive structures are positioned between the first and second photodetectors in a plan view of the IC device; and
at least a portion of the second and fourth conductive structures are positioned at a periphery of at least one of the first photodetector or the second photodetector in the plan view of the IC device.

7. The IC device of claim 1, wherein the first capacitor electrode is electrically coupled to a photodetector within the first IC die and the second capacitor electrode is electrically coupled to a reference voltage structure.

8. An integrated circuit (IC) device, comprising:
a first IC die comprising a first plurality of conductive structures within a first dielectric structure disposed on a first substrate, the first plurality of conductive structures and the first dielectric structure arranged along a first surface of the first IC die; and
a second IC die comprising a second plurality of conductive structures arranged within a second dielectric structure disposed on a second substrate, the second plurality of conductive structures and the second dielectric structure arranged along a first surface of the second IC die, wherein the first surface of the first IC die faces and contacts the first surface of the second IC die to form a die interface;
wherein a plurality of capacitors straddle the die interface, the plurality of capacitors comprising a plurality of first capacitor plates and a plurality of second capacitor plates that are laterally separated along the die interface, the plurality of first capacitor plates and the plurality of second capacitor plates comprising the first plurality of conductive structures and the second plurality of conductive structures.

9. The IC device of claim 8, wherein the first IC die further comprises a plurality of photodetectors, each of the plurality of photodetectors electrically coupled to one of the plurality of first capacitive plates, and wherein the plurality of second capacitive plates are connected to a reference voltage structure.

10. The IC device of claim 8, wherein:
the first plurality of conductive structures comprise a first conductive structure arranged within a pixel region comprising one or more photodiodes and a second conductive structure arranged laterally between the pixel region and an adjacent pixel region; and
the second plurality of conductive structures comprise a third conductive structure contacting the first conductive structure to form one of the plurality of first capacitor plates and a fourth conductive structure contacting the second conductive structure to form one of the plurality of second capacitor plates.

11. The IC device of claim 10, wherein the one of the plurality of first capacitive plates is centrally disposed within the pixel region in a plan view of the IC device.

12. The IC device of claim 10, wherein the one of the plurality of second capacitive plates is circular and disposed at a corner of the pixel region in a plan view of the IC device.

13. The IC device of claim 10, wherein the plurality of the second capacitive plates forms a conductive comb structure comprising a plurality of conductive branches, one of the plurality of conductive branches extending along a peripheral edge of the pixel region in a plan view of the IC device.

14. The IC device of claim 10, wherein the plurality of the second capacitive plates forms a conductive mesh structure comprising a plurality of conductive segments, two of the plurality of conductive segments intersecting one another and extending along adjacent peripheral edges of the pixel region in a plan view of the IC device.

15. The IC device of claim 8, wherein each of the plurality of first capacitive plates and each of the plurality of second capacitive plates comprise:
one of the plurality of first conductive structures;
a first conductive contact connected to a side of the one of the plurality of first conductive structures opposite the first surface of the first IC die;
one of the plurality of second conductive structures; and
a second conductive contact connected to a side of the one of the plurality of second conductive structures opposite the first surface of the second IC die.

16. The IC device of claim 15, wherein:
a width of the one of the plurality of first conductive structures is greater than a width of the first conductive contact in a plan view of the first IC die; and
a width of the one of the plurality of second conductive structures is greater than a width of the second conductive contact in a plan view of the second IC die.

17. A method, comprising:
for each of a first IC die and a second IC die:
forming a first dielectric layer over a first upper conductive structure and a second upper conductive structure;
forming a second dielectric layer over the first dielectric layer;
etching a first trench and a second trench through the second dielectric layer and the first dielectric layer, the first trench having a first width and the second trench having a second width in a cross-sectional view;
etching a third trench within the first trench through the second dielectric layer and a fourth trench within the second trench through the second dielectric layer, the third trench having a third width greater than the first width and the fourth trench having a fourth width greater than the second width in the cross-sectional view; and
forming a first conductive element in the first trench and the third trench and a second conductive element in the second trench and the fourth trench, the first conductive element contacting the first upper conductive structure, and the second conductive element contacting the second upper conductive structure; and
bonding an upper surface of the first IC die to an upper surface of the second IC die to form a capacitor comprising the first conductive elements and the second conductive elements.

18. The method of claim 17, wherein the bonding of the upper surface of the first IC die to the upper surface of the second IC die comprises a heat-based bonding.

19. The method of claim 17, further comprising:
for each of the first IC die and the second IC die, planarizing the upper surface after forming the first and second conductive elements.

20. The method of claim 17, wherein the capacitor couples a portion of a photodetector circuit to a reference voltage structure.
